(19) United States
(12) Patent Application Publication
(10) Pub. No.: US 2026/0038731 A1
(43) Pub. Date: Feb. 5, 2026

(54) INDUCTOR-BASED VOLTAGE CONVERTERS FOR MEMORY APPARATUSES

(71) Applicant: Micron Technology, Inc., Boise, ID (US)

(72) Inventors: Carlos Jesus Franco Tinoco, Boise, ID (US); Ekram H. Bhuiyan, Sunnyvale, CA (US); Dustin L. Holloway, Meridian, ID (US); Dale Arnold, Meridian, ID (US); Scott L. Willmorth, Meridian, ID (US); Jonathan S. Parry, Boise, ID (US); Aniket Bhandare, Boise, ID (US)

(21) Appl. No.: 19/274,883

(22) Filed: Jul. 21, 2025

Related U.S. Application Data
(60) Provisional application No. 63/677,820, filed on Jul. 31, 2024.

(51) Int. Cl. H01F 27/28; G11C 16/30; H02M 3/00; H02M 3/158

(52) U.S. Cl. CPC H01F 27/2885; G11C 16/30; H02M 3/003; H02M 3/1582

(57) ABSTRACT

Apparatuses and methods are provided for a memory system having an inductor-based voltage converter integrated within a multilayer substrate of a controller of the memory system, or within a multilayer substrate of a power management integrated circuit (PMIC), or both.

### PRIORITY INFORMATION

This application claims the benefit of U.S. Provisional Application No. 63/677,820, filed Jul. 31, 2024, the contents of which are incorporated herein by reference.

### TECHNICAL FIELD

The present disclosure relates generally to electronic systems, and more particularly to inductor-based voltage converters for memory apparatuses such as storage systems.

### BACKGROUND

A memory system can be a storage system, such as a solid-state drive (SSD) or a universal flash storage (UFS) based storage system, which can include one or more memory components that store data. The memory components can be, for example, non-volatile memory components and volatile memory components. In general, a host system can utilize a memory system to store data at the memory components and to retrieve data from the memory components.

Various memory systems include voltage converters that can adjust (e.g., increase or decrease) voltages supplied to various system components (e.g., controllers, memory devices, input/output interfaces, etc.).

### BRIEF DESCRIPTION OF THE DRAWINGS

FIG. 1 illustrates an example computing environment that includes a memory system having an inductor-based voltage converter in accordance with various embodiments of the present disclosure.

FIG. 2 illustrates a plan view of an example inductor-based voltage converter that can be integrated in a memory system in accordance with a number of embodiments of the present disclosure.

FIG. 3A illustrates a top view of a first layer of the example inductor-based voltage converter in accordance with a number of embodiments of the present disclosure.

FIG. 3B illustrates a top view of a second layer of the example inductor-based voltage converter in accordance with a number of embodiments of the present disclosure.

FIG. 3C illustrates a top view of a third layer of the example inductor-based voltage converter in accordance with a number of embodiments of the present disclosure.

FIG. 3D illustrates a top view of a fourth layer of the example inductor-based voltage converter in accordance with a number of embodiments of the present disclosure.

### DETAILED DESCRIPTION

Embodiments of the present disclosure describe apparatuses and methods associated with inductor-based voltage converters within memory systems. Example memory systems can include multichip package (MCP) storage systems such as a UFS-based MCP (uMCP), a managed NAND (mNAND), etc. Such MCPs can include multiple memory types (e.g., DRAM, NAND, etc.) and a controller (e.g., ASIC) in a single package. Reducing or maintaining the size and cost of the MCP storage systems while increasing thermal and power efficiency is desirable, particularly for mobile applications such as cellular phones. MCP storage systems often utilize low dropout (LDO) regulators to regulate the voltages supplied to various system components. Other voltage converters such as buck converters, boost converters, buck-boost converters, etc. can provide increased power efficiency as compared to LDO solutions. However, converters such as switching DC/DC buck converters employ inductors to perform the step-down voltage conversion, and implementing sufficiently sized inductors within the limited real estate of the MCP storage system may not be possible. For example, MCP storage systems often include multilayer substrates having 4 or fewer layers and a total height of less than 200 micrometers; although, embodiments are not so limited. Additionally, for mobile applications, it is desired for the inductors to include low equivalent series resistance (ESR) and shielding to reduce/minimize electromagnetic interference (EMI). Such shielding can reduce the inductance magnitude (e.g., due to induced parasitic currents) and can occupy one or more of the limited quantity of substrate layers.

Various embodiments described herein address the issues of prior approaches by providing an MCP storage system having an inductor-based voltage converter (e.g., a switching DC/DC buck converter) that can be implemented in the controller (e.g., ASIC chip) and/or a power management integrated circuit (PMIC), for example. In various embodiments, the MCP substrate in which the inductor-based voltage converter is implemented comprises four or fewer layers; however, embodiments are not limited to a particular quantity of substrate layers. The MCP substrate can be a coreless substrate or a traditional substrate. As described further herein, various embodiments can include one or more shielding layers above and/or below the layers in which the inductor loops are drawn. The ground shielding can be a solid conductive shielding layer. However, various embodiments include a shielding pattern that does not include continuous conductive loops, which can reduce/prevent eddy currents (e.g., due to path discontinuity and asymmetry). As an example, the shielding pattern can comprise a number of discontinuous elongate extensions, which may be referred to as “fingers” extending in one or multiple directions (e.g., “x” and/or “y” directions). Such shielding patterns can be useful to prevent parasitic current within the shielding layers, which would otherwise serve to cancel the inductance of the inductor loops of the converter.

Although example embodiments describe the inductor-based voltage converter as a DC/DC buck or boost converter, the present disclosure is not so limited. For example, the inductor-based voltage converter drawn in a multilayer substrate (e.g., of a controller, PMIC, etc.) can also be other types of voltage converters.

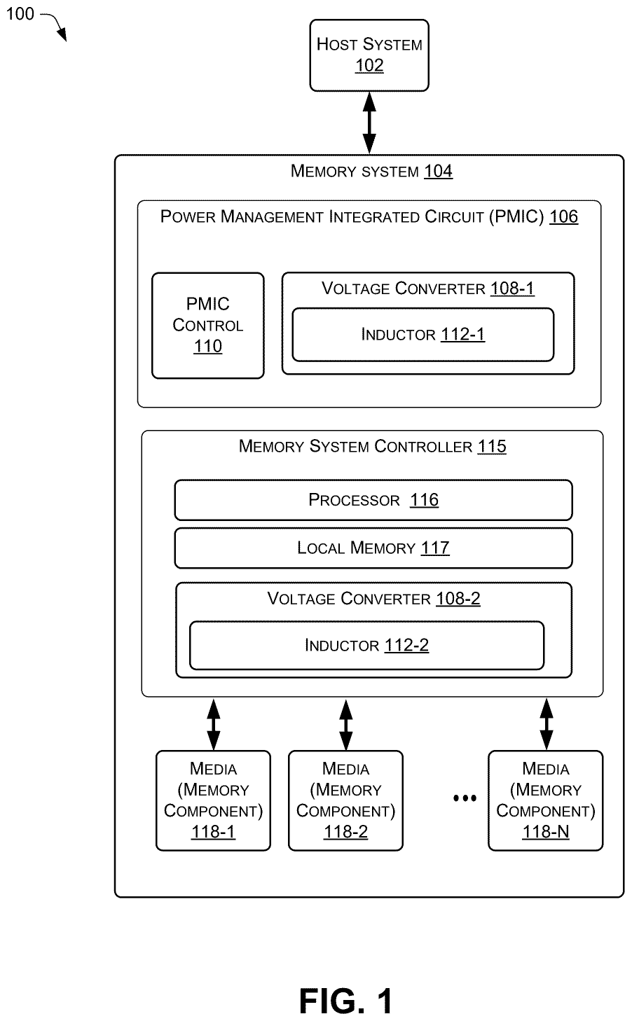

FIG. 1 illustrates an example computing environment 100 that includes a memory system 104 in accordance with some embodiments of the present disclosure. In some embodiments, a host system 102 is coupled to the memory system 104 to read data from or write data to the memory system 104. The memory system 104 may further include a power management component such as a power management integrated circuit (PMIC) 106, a memory system controller 115, and memory components 118-1 to 118-N. In various embodiments, the PMIC 106 and/or controller 115 can be separate chips within an MCP. The memory system 104 can be a storage device, a memory module, or a hybrid of a storage device and a memory module. Examples of storage devices include a solid-state drive (SSD), a managed NAND (mNAND), a Universal Flash Storage (UFS) drive, a secure digital (SD) card, and a hard disk drive (HDD). Examples of memory modules include a dual in-line memory module (DIMM) and various types of non-volatile dual in-line memory modules (NVDIMMs). In general, the host 102 can utilize the memory system 104 which includes one or more memory components. The host 102 can provide data to be stored at the memory system 104 and can request data to be retrieved from the memory system 104.

The host system 102 can be a computing device such as a desktop computer, laptop computer, network server, mobile device, or such computing device that includes a memory and a processing device. The host system 102 can be coupled to the memory system 104 via a physical host interface. As used herein, “coupled to” generally refers to a connection between components, which can be an indirect communicative connection or direct communicative connection (e.g., without intervening components), whether wired or wireless, including connections such as electrical, optical, magnetic, etc. Examples of a physical host interface include but are not limited to, a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 102 and the memory system 104. The host system 102 can further utilize an NVM Express (NVMe) interface to access the memory components 118-1 to 118-N when the memory system 104 is coupled with the host system 102 by the PCIe interface. The physical host interface can provide an interface for passing control, address, data, and other signals between the memory system 104 and the host system 102.

The memory components 118-1 to 118-N can include various combinations of the different types of non-volatile memory components and/or volatile memory components. An example of non-volatile memory component includes a NAND flash memory. Each of the memory components 118-1 to 118-N can include one or more arrays of memory cells such as single-level cells (SLCs) or multi-level cells (MLCs) (e.g., triple-level cells (TLCs) or quad-level cells (QLCs)). In some embodiments, a particular memory component can include both an SLC portion and an MLC portion of memory cells. Each of the memory cells can store one or more bits of data (e.g., data blocks) used by the host system 102. Although non-volatile memory components such as NAND type flash memory are described, the memory components 118-1 to 118-N can be based on various memory technologies and/or array architectures. In some embodiments, the memory components 118-1 to 118-N can be but are not limited to, random access memory (RAM), read-only memory (ROM), dynamic random access memory (DRAM), synchronous dynamic random access memory (SDRAM), phase change memory (PCM), magneto random access memory (MRAM), negative-or (NOR) flash memory, electrically erasable programmable read-only memory (EEPROM), and which can be arranged as a planar array, a cross-point array, three-dimensional cross-point array, etc.

The memory system controller 115 can communicate with the memory components 118-1 to 118-N to perform operations such as reading data, writing data, or erasing data at the memory components 118-1 to 118-N and other such operations. The memory system controller 115 can include hardware such as one or more integrated circuits and/or discrete components, a buffer memory, or a combination thereof. The memory system controller 115 can be a microcontroller, special purpose logic circuitry (e.g., a field programmable gate array (FPGA), an application specific integrated circuit (ASIC), etc.), or other suitable processing circuitry. The memory system controller 115 can include a processing device (e.g., processor 116) configured to execute instructions stored in a local memory 117.

The local memory 117 of the memory system controller 115 includes an embedded memory configured to store instructions for performing various processes, operations, logic flows, and routines that control the operation of the memory system 104, including handling communications between the memory system 104 and the host system 102. In some embodiments, the local memory 117 can include memory registers storing memory pointers, fetched data, etc. The local memory 117 can also include read-only memory (ROM) for storing microcode.

In general, the memory system controller 115 can receive commands or operations from the host system 102 and can convert the commands or operations into instructions or appropriate commands to achieve the desired access to the memory components 118-1 to 118-N. The memory system controller 115 can be responsible for other operations such as wear leveling operations, garbage collection operations, error detection and error-correcting code (ECC) operations, encryption operations, caching operations, and address translations between a logical block address and a physical block address that are associated with the memory components 118-1 to 118-N. The memory system controller 115 can further include host interface circuitry to communicate with the host system 102 via a physical host interface (not shown). The host interface circuitry can convert the commands received from the host system into command instructions to access the memory components 118-1 to 118-N as well as convert responses associated with the memory components 118-1 to 118-N into information for the host system 102.

The memory system 104 can also include additional circuitry or components that are not illustrated. For instance, the memory components 118-1 to 118-N can include control circuitry (e.g., a local controller), address circuitry (e.g., row and column decode circuitry), and/or input/output (I/O) circuitry by which they can communicate with memory system controller 115 and/or host system 102. As an example, in some embodiments, the address circuitry (not shown) can receive an address from the memory system controller 115 and decode the address to access the memory components 118-1 to 118-N.

The PMIC 106 can be a chip configured to manage power within the system 104. For example, the PMIC 106 can include one or more voltage converters (e.g., 108-1) to generate output voltages (e.g., rail voltages) such as I/O rails, reference rails, etc. that are provided to power various system components, such as controller 115, memory components 118, and/or interfaces associated therewith.

As shown in FIG. 1, the PMIC 106, memory system controller 115, or both, may include corresponding voltage converters (e.g., 108-1 and 108-2, which are referred to collectively as voltage converters 108). As described further herein, the voltage converters 108 can be inductor-based voltage converters (e.g., D/C buck converters) that include corresponding inductors (e.g., 112-1 and 112-2), which can be drawn in the substrate of the respective controller chip and/or PMIC chip, for example. MCP storage systems such as system 104 often have a reduced thickness (e.g., limited quantity of substrate and/or thin substrate layers), which provides limited available real estate for inductor-based voltages converters such as 108-1 and 108-2. For example, in various embodiments, the inductors 112-1 and/or 112-2 may include only one or two inductor coils depending on the quantity available substrate layers and/or depending on whether or not one or more shielding layers are needed.

The PMIC 106 includes control circuitry 110, which is configured to control the various components of the PMIC 106, such as voltage converter 108-1. Although not shown in FIG. 1, the voltage converters 108 include additional circuitry such as input/output capacitors, diodes, transistor switches, fuses, feedback networks, etc.

As described further below, the inductors 112-1 and 112-2 may include one or more conductive coils or loops and shielding, and/or vias that connect the coils with one another or to the ground, for example. Although not shown, the inductors 112-1 and 112-2 are coupled to other components of the voltage converter to which they correspond (e.g., capacitors, diodes, transistors, etc.) to generate the desired output voltages. In various embodiments, one or more coreless inductor 112 may be formed in the multilayer substrate of the PMIC 106, memory system controller 115, or both.

Embodiments are not limited to the example shown in FIG. 1. For example, the system controller 115 may not include a voltage converter. That is, the PMIC 106 may include all of the voltage converters for the system. As another example, the system 104 may not include a PMIC 106. In such embodiments, the inductor-based voltage converters 108 can be drawn in the substrate of the controller 115, for example.

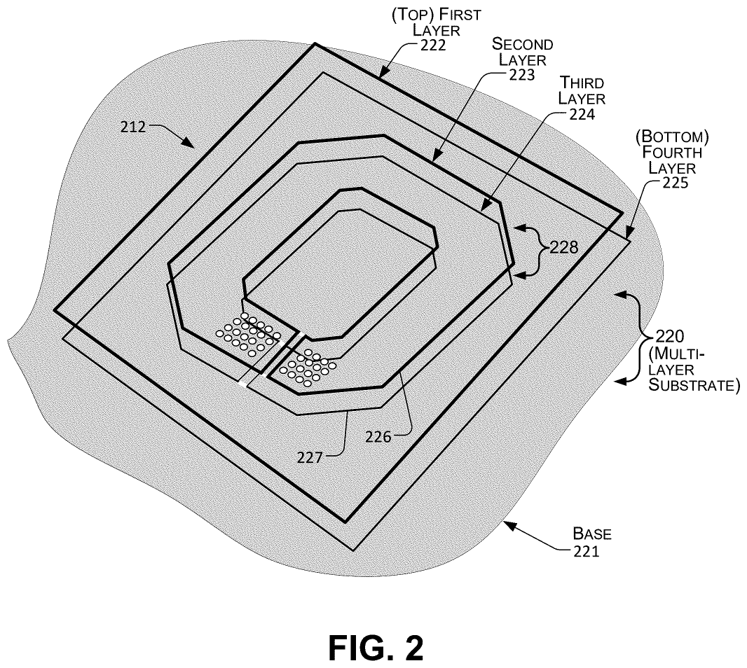

FIG. 2 is an example plan view of an inductor 212 in accordance with a number of embodiments of the present disclosure. The inductor 212 can be analogous to the inductor 112-1 or 112-2 described in FIG. 1. For example, the inductor 212 can be integrated into a multilayer substrate (e.g., 220) of a storage system (e.g., a MCP storage system), which can be within a mobile phone, a tablet computer, a netbook, laptop, personal digital assistance, digital camera, etc. As described further herein, the inductor 212 can be a component of a voltage converter (e.g., 108-1/108-2 shown in FIG. 1) such as a DC/DC buck converter used to regulate an input voltage (e.g., a supply voltage).

In various embodiments, the components (e.g., chips) of an MCP storage system, such as system 104 shown in FIG. 1, comprise a multilayer substrate (e.g., 220). The quantity of layers can be 4 or fewer; however, embodiments are not so limited. For example, the multilayer substrate 220 includes four layers (e.g., a first/top layer 222, a second layer 223, a third layer 224, and a fourth/bottom layer 225), which can be coupled to a base 221, such as a Printed Circuit Board (PCB). The substrate can have a thickness of less than 200 micrometers (um). In some embodiments, the substrate has a thickness of 150 um or less.

As described herein, the multilayer substrate 220 refers to multiple stacked layers of materials. The layers can be composed of various substrate materials and the choice of materials for each layer may depend on specific requirements of the device being fabricated. For example, a layer can be formed to include an insulating layer, a conductive trace, or a combination of both. In a coreless substrate, conductive traces (226, 227) can be patterned on a surface layer of an insulating dielectric material. In this example, the dimensions of each layer can be leveraged to form the inductor 212 of a voltage converter that regulates an input voltage to generate the desired corresponding output voltage(s).

In a number of embodiments, the conductive traces 226 and 227 may be formed on the layers 223 and 224, respectively. The conductive trace 226 and 227 may respectively include conductive materials of a particular shape and dimension. As an example, the conductive traces can comprise copper. The traces 226 and 227 can form respective coils/loops of the inductor 212. As an example, the conductive traces can be substantial mirror copies; although embodiments are not so limited. The conductive traces 226 and 227 can be parallel with each other, can have substantially equal shapes, and can be vertically aligned. The term “substantially” intends that the characteristic need not be absolute but is close enough to achieve the advantages of the characteristic. For example, “substantially parallel” is not limited to characteristics that are absolutely parallel and can include characteristics that are intended to be parallel but due to manufacturing limitations may not be precisely parallel.

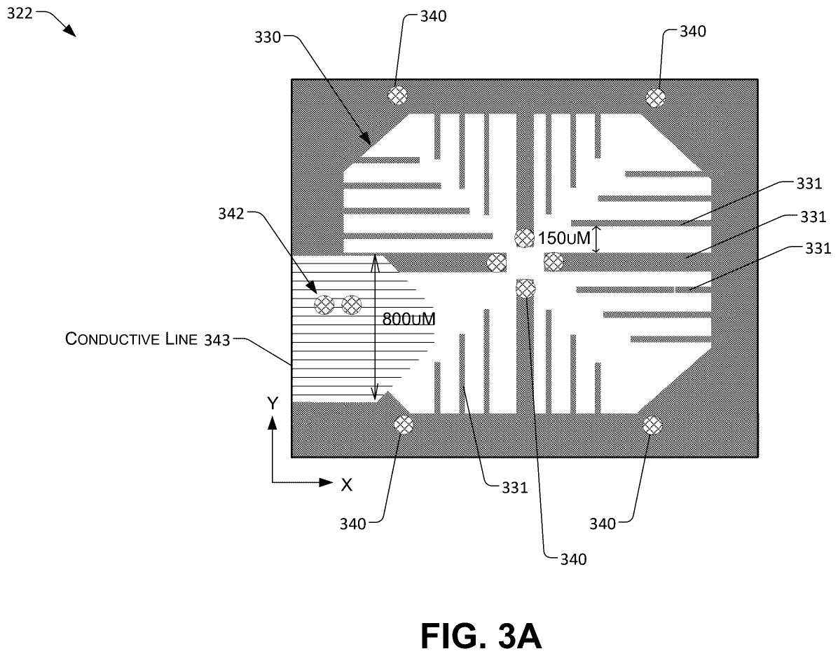

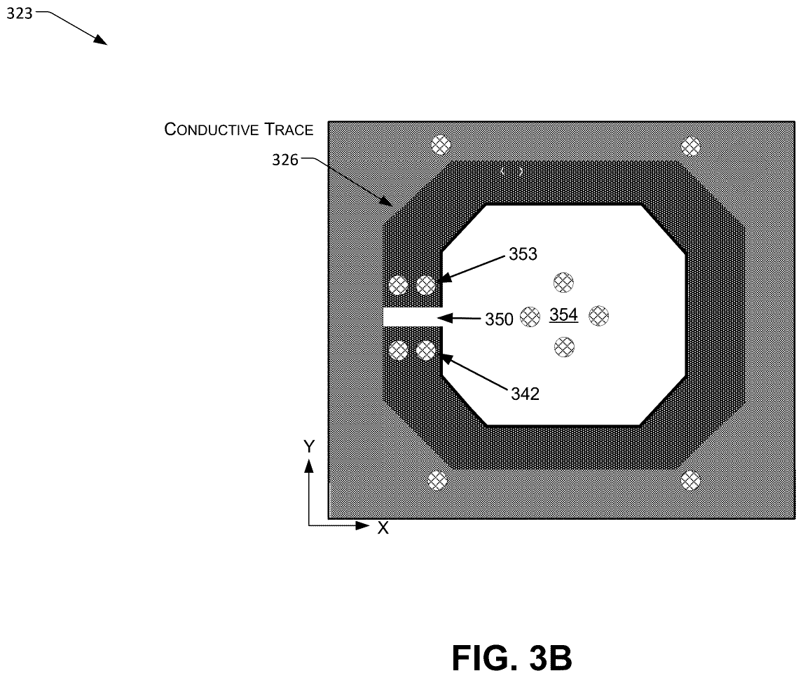

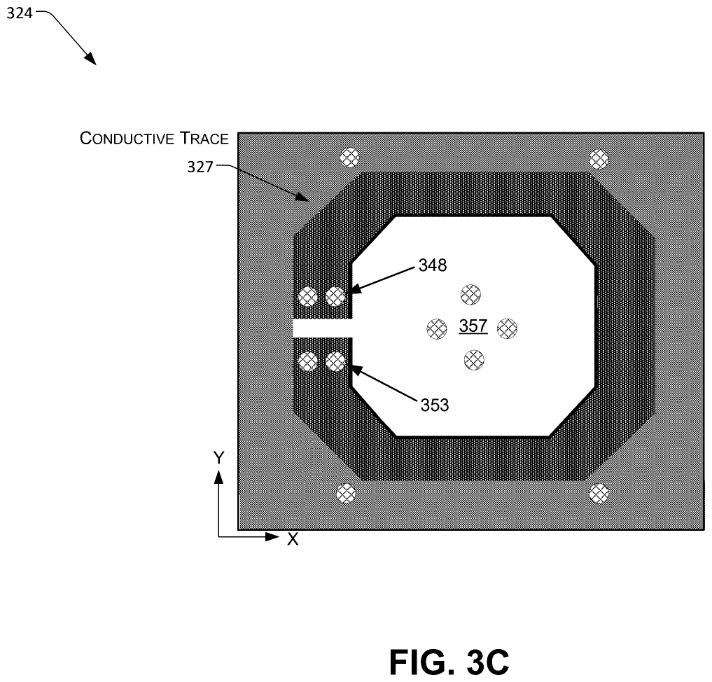

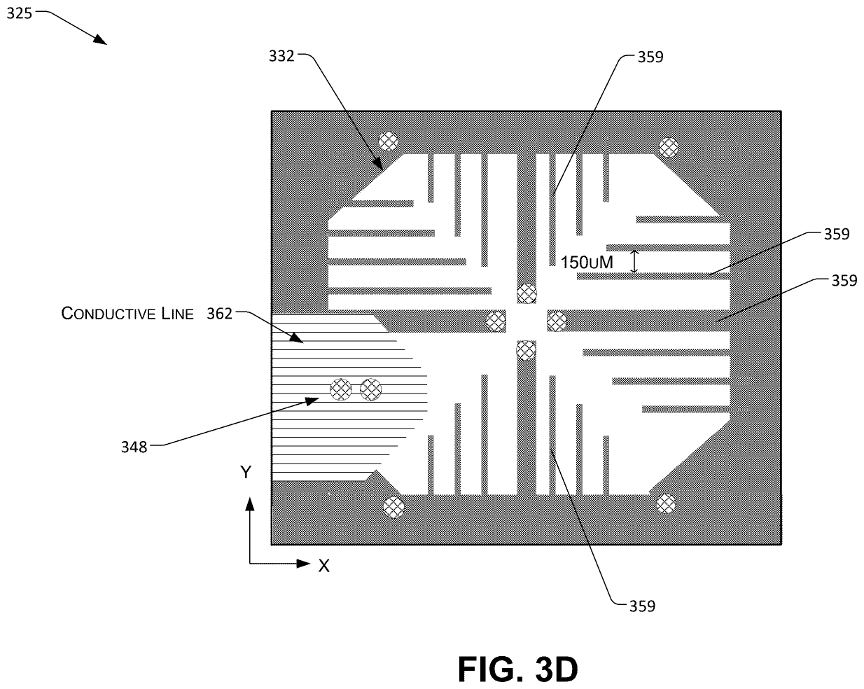

Although not shown in FIG. 2, the various layers of the multilayer substrate 220 can be interconnected using interconnecting vias (e.g., micro vias). For example, the first layer 222 is coupled to the second layer 223; the second layer 223 is coupled to the third layer 224; the third layer 224 is coupled to the fourth layer 225; and the fourth layer 225 is coupled to the first layer 222. The vias may connect a conductive line/material to a conductive trace, connect the conductive line to ground, connect ground in one layer to another ground in another layer, or a combination thereof. For example, the multilayer substrate 220 can include a number of ground vias (e.g., vias 340 shown in FIG. 3A) surrounding the inductor 212.

Although not shown in FIG. 2, the inductor 212 is part of a voltage converter that can include various other circuitry components (capacitors, diodes, transistor switches, etc.) formed in the multilayer substrate 220.

In a number of embodiments, one or more substrate layers may include a shielding layer for the inductor (e.g., 212). For example, the top substrate layer (e.g., 222) and/or the bottom substrate layer (225) may be configured to provide shielding to the conductive traces 228 during operation of the voltage converter to which the inductor 212 corresponds. In this example, the conductive traces 226 and 227 are patterned to include an octagonal-shaped coreless conductive loop of a particular width, thickness, and/or length.

During operation, the shielding layers can provide the proper grounding to minimize the risk of electromagnetic leakage, while reducing EMI and/or parasitic capacitances, which can adversely affect the voltage converter effectiveness and/or efficiency, for example.

In embodiments in which the first layer 222 and/or the fourth layer 225 are shielding layers, the shielding layers can have various configurations. For instance, in some embodiments, the shielding can be a “solid” shielding, which can comprise a planar conductive sheet serving as a ground shielding pattern. In various instances, eddy current loops may form in such solid shielding patterns, which can generate magnetic fields that can adversely affect (e.g., cancel) the inductance of the inductor 212.

In various embodiments, instead of having a planar/solid shielding configuration, the shielding layer (e.g., 222 and/or 225) can have a shielding pattern comprising a number of discontinuous finger-like conductive structures. The “fingers” can be discontinuous and can extend in multiple directions (e.g., x and y directions) while not forming closed current loops. Such shielding patterns, examples of which are shown in FIG. 3A and 3D, can provide benefits such as preventing parasitic eddy current loops in the shielding layer due to the discontinuity and/or asymmetry of the shielding pattern. Such shielding patterns can be especially beneficial in instances in which the inductor 212 comprises only one or two loops such that the inductance value is low (e.g., below 5 nH) such that further lowering of the inductance due to parasitic currents can be detrimental to the operation of the corresponding voltage converter.

In some embodiments, the shielding layers 222 and/or 225 may comprise insulators.

FIGS. 3A-3D show example respective top views of a number of layers of a multilayer substrate having an inductor-based voltage converter formed therein in accordance with various embodiments of the present disclosure. Although embodiments are not so limited, this example includes a four layer substrate including a first layer 322 (FIG. 3A), a second layer 323 (FIG. 3B), a third layer 324 (FIG. 3C), and a fourth layer 325 (FIG. 3D. The layers 322 to 325 can be analogous to respective layers 222 to 225 shown in FIG. 2.

In the example shown in FIGS. 3A-3D, the two interior layers 323 and 324 comprise inductor loops formed by respective conductive traces 326 and 327. As described herein, the inductor loops 326 and 327 can serve as a power inductor of a voltage converter such as a switching DC/DC buck converter;

however, embodiments are not limited to a particular type of power converter/regulator. In this example, the top layer 322 and bottom layer 325 comprise shielding layers. The shielding illustrated in FIGS. 3A and 3C comprises a shielding pattern (330, 332) designed to reduce EMI as compared to prior shielding approaches such as solid shielding, for instance.

FIG. 3A is a top view of the inductor shielding of layer 322 of the multilayer substrate. The shielding pattern 330 is designed to reduce/minimize EMI while reducing/preventing the presence of parasitic currents within the shielding layers, which would otherwise reduce (e.g., cancel) the inductance magnitude of the inductor formed in layers 323 and 324. In this example, the shielding pattern 330 comprises multiple conductive “fingers” 331 that are discontinuous in that they do not form continuous conductive loops which would create parasitic current loops. The conductive fingers 331 extend in different directions (e.g., x and y). As shown, the fingers 331 are either parallel or perpendicular to each other; although, embodiments are not limited to a particular discontinuous and/or asymmetric shielding pattern.

As shown in FIG. 3A, the layer 322 can include a conductive line 343 that can serve as a power line for the voltage converter. Although not shown in FIG. 3A, the conductive line 343 is electrically isolated from the inductor shielding of layer 322. The layer 322 can include a number of vias 340 that can, for example, serve as ground connections (e.g., a ground via array). The vias 340 are not limited to a particular quantity and/or to a particular placement. A number of vias 342 (e.g., power vias) can serve to electrically couple the conductive line 343 to other portions of the multilayer substrate (e.g., to conductive trace 326 of layer 323 shown in FIG. 3B). The vias 340 and/or 342 can be micro vias (uvias).

FIG. 3B is a top view of a first interior layer 323 of the multilayer substrate, and FIG. 3C is a top view of a second interior layer 324 of the multilayer substrate. The layers 323 and 324 include conductive traces 326 and 327, which provide respective first and second inductor loops of an inductor corresponding to an inductor-based voltage converter in accordance with embodiments described herein. The coils 326 and 327 can be coupled between layers 323 and 324 (e.g., using micro vias 353 to provide a continuous current path through the inductor coil(s). Micro vias 348 can couple an end of conductive loop 327 to the conductive line 362 of layer 325 shown in FIG. 3D. The power vias (e.g., 342, 353, 358) may be positioned at different locations to provide a series or parallel connection of the traces/loops, which can depend on the inductance targeted for implementation. In this example, the inductor is coreless as indicated by the open centers 354 and 357 of respective inductor traces 326 and 327.

FIG. 3D is a top view of the inductor shielding of layer 325 of the multilayer substrate. Similar to the shielding pattern 330 of FIG. 3A, the shielding pattern 332 is designed to reduce/minimize EMI while reducing/preventing the presence of parasitic currents within the shielding layers, which would otherwise reduce (e.g., cancel) the inductance magnitude of the inductor formed in layers 323 and 324. In this example, the shielding pattern 332 comprises multiple conductive “fingers” 359 that are discontinuous in that they do not form continuous conductive loops which would create parasitic current loops. The conductive fingers 359 extend in different directions (e.g., x and y). As shown, the fingers 359 are either parallel or perpendicular to each other; although, embodiments are not limited to a particular discontinuous and/or asymmetric shielding pattern. For example, the fingers 359 may be formed at angles other than 90 degrees with respect to each other.

As shown in FIG. 3D, the layer 325 can include a conductive line 362 that can connect the inductor to other circuitry of the voltage converter. The conductive line 362 can be electrically isolated from the shielding of layer 325. The layer 325 includes vias 348 serving to couple line 362 to an end of conductive trace 327 of layer 324.

The figures herein follow a numbering convention in which the first digit or digits correspond to the drawing figure number and the remaining digits identify an element or component in the drawing. Similar (e.g., the same) elements or components between different figures may be identified by the use of similar digits. For example, identifier 223 can refer to element “23” in FIG. 2, and a similar element in can be referred to using identifier 323 in FIG. 3. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of turns can refer to one or more turns. A “plurality” of something intends two or more. As used herein, multiple acts being performed concurrently refer to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause-and-effect relationship). An element coupled between two elements can be between the two elements and coupled to each of the two elements. Unless stated otherwise, where a single element is discussed, it is understood that all similar elements are referred to.

It should be recognized the term planar accounts for variations from “exactly” planar due to routine manufacturing, measuring, and/or assembly variations and that one of ordinary skill in the art would know what is meant by the term “planar.”

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. An apparatus, comprising:
a number of memory components;
a controller coupled to the number of memory components; and
a voltage converter coupled to the controller and comprising an inductor integrated within a multilayer substrate of the controller, or integrated within a multilayer substrate of a power management integrated circuit, or both.

2. The apparatus of claim 1, wherein the apparatus is a storage system selected from a group comprising:
a managed NAND storage system; and
a UFS based storage system.

3. The apparatus of claim 1, wherein the voltage converter is a DC/DC buck converter.

4. The apparatus of claim 1, wherein the inductor further comprises:
a first conductive trace formed on a first layer of the multilayer substrate; and
a second conductive trace formed on a second layer of the multilayer substrate.

5. The apparatus of claim 4, wherein the voltage converter includes shielding on a top layer of the multilayer substrate or a bottom layer of the multilayer substrate, or both.

6. The apparatus of claim 5, wherein the shielding comprises a shielding pattern lacking closed conductive loops to prevent eddy currents therein.

7. The apparatus of claim 6, wherein the shielding pattern comprises a plurality of discontinuous conductive fingers.

8. The apparatus of claim 7, wherein the discontinuous conductive fingers include a first number of fingers extending in a direction perpendicular to a direction in which a second number of fingers extend.

9. The apparatus of claim 1, wherein the multilayer substrate has a thickness of 150 micrometers or less.

10. A system, comprising:
a number of memory components of a multichip package (MCP) storage system; and
a controller of the MCP storage system, wherein the controller is coupled to the number of memory components and comprises a number of substrate layers;
wherein the controller includes a voltage converter comprising an inductor formed in one or more of the number of substrate layers.

11. The system of claim 10, wherein the voltage converter is a DC/DC buck converter, boost converter, or buck-boost converter.

12. The system of claim 10, further comprising a host processor coupled to the MCP storage system.

13. The system of claim 10, wherein the inductor comprises:
only one inductor loop formed in a first substrate layer of the number of substrate layers; or
only two inductor loops, with a first inductor loop formed in the first substrate layer and a second inductor loop formed in a second substrate layer.

14. The system of claim 13, wherein the number of substrate layers comprises four or fewer layers.

15. The system of claim 14, wherein the inductor loops are formed between a bottom layer and a top layer of the number of substrate layers, and wherein a shielding for the voltage converter is formed in at least one of the bottom layer and the top layer.

16. The system of claim 15, wherein the shielding comprises a shielding pattern comprising multiple discontinuous fingers.

17. An apparatus, comprising:
a number of memory components of a storage system;
a system controller chip coupled to the number of memory components and comprising a substrate comprising a plurality of substrate layers; and
a voltage converter integrated within the substrate and having an inductor comprising an inductor loop formed in at least one interior layer of the plurality of substrate layers, and inductor shielding formed in at least one exterior layer of the plurality of substrate layers;
wherein the inductor shielding comprises a shielding pattern having a plurality of elongate conductive extensions that are discontinuous and configured to prevent eddy current loops.

18. The apparatus of claim 17, wherein the apparatus is one of a managed NAND storage system or a UFS based storage system, and wherein the plurality of substrate layers comprises four or fewer layers.

19. The apparatus of claim 18, wherein the substrate is a coreless substrate having a total thickness of less than 200 micrometers.

20. The apparatus of claim 19, wherein the inductor comprises two or fewer inductor loops.
